(19) United States
(12) Patent Application Publication
(10) Pub. No.: US 2024/0379510 A1
(43) Pub. Date: Nov. 14, 2024

(54) CIRCUIT COMPONENT, ELECTRONIC DEVICE AND METHOD FOR PRODUCING CIRCUIT COMPONENT

(71) Applicant: ROHM CO., LTD., Kyoto-shi (JP)

(72) Inventor: Katsuhiko YOSHIHARA, Kyoto-shi (JP)

(21) Appl. No.: 18/782,758

(22) Filed: Jul. 24, 2024

Related U.S. Application Data
(63) Continuation of application No. PCT/JP2023/001891, filed on Jan. 23, 2023.

(30) Foreign Application Priority Data
Feb. 4, 2022 (JP) 2022-016239

(51) Int. Cl. H01L 23/495; H01L 23/00; H01L 23/31

(52) U.S. Cl. CPC H01L 23/49575; H01L 23/3107; H01L 24/32; H01L 24/48; H01L 24/73; H01L 2224/32245; H01L 2224/40153; H01L 2224/48137; H01L 2224/48175; H01L 2224/73221; H01L 2224/73263; H01L 2224/73265

(57) ABSTRACT

A semiconductor device includes a first conductive member, a second conductive member spaced apart from the first conductive member in a first direction, a first semiconductor element bonded to the first conductive member, a second semiconductor element bonded to the second conductive member, a third conductive member, a fourth conductive member electrically connecting the first semiconductor element to the second conductive member, and a fifth conductive member electrically connecting the second semiconductor element to the third conductive member. The third conductive member includes a first portion located between the first semiconductor element and the second semiconductor element in the first direction, and the first portion faces the first conductive member in the thickness direction. One end of the fifth conductive member is bonded to the first portion. The fourth conductive member straddles the first portion.

### TECHNICAL FIELD

The present disclosure relates to a semiconductor device.

### BACKGROUND ART

Semiconductor devices with semiconductor elements such as switching elements are conventionally known. An example of a conventional semiconductor device is disclosed in WO-A1-2019/098368. The semiconductor device disclosed in WO-A1-2019/098368 includes a plurality of first switching elements, a plurality of second switching elements, a first power supply terminal, and a second power supply terminal. The second power supply terminal includes a first strip portion, a plurality of second strip portions, and an external connection portion. The plurality of second strip portions and the plurality of second switching elements are individually connected to each other with a plurality of second conduction wires. A plurality of first conduction wires are individually connected to the plurality of first switching elements.

### BRIEF DESCRIPTION OF THE DRAWINGS

FIG. 1 is a plan view of a semiconductor device according to a first embodiment of the present disclosure.

FIG. 2 is a bottom view of the semiconductor device according to the first embodiment of the present disclosure.

FIG. 3 is a side view of the semiconductor device according to the first embodiment of the present disclosure.

FIG. 4 is a sectional view taken along line IV-IV in FIG. 1.

FIG. 5 is a sectional view taken along line V-V in FIG. 1.

FIG. 6 is a sectional view taken along line VI-VI in FIG. 1.

FIG. 7 is a sectional view taken along line VII-VII in FIG. 1.

FIG. 8 is a sectional view taken along line VIII-VIII in FIG. 1.

FIG. 9 is a sectional view taken along line IX-IX in FIG. 1.

FIG. 10 is a sectional view taken along line X-X in FIG. 1.

FIG. 11 is a sectional view taken along line XI-XI in FIG. 1.

FIG. 12 is a sectional view showing a first variation of the semiconductor device according to the first embodiment of the present disclosure.

FIG. 13 is a sectional view showing a second variation of the semiconductor device according to the first embodiment of the present disclosure.

FIG. 14 is a plan view of a semiconductor device according to a second embodiment of the present disclosure.

FIG. 15 is a sectional view taken along line XV-XV in

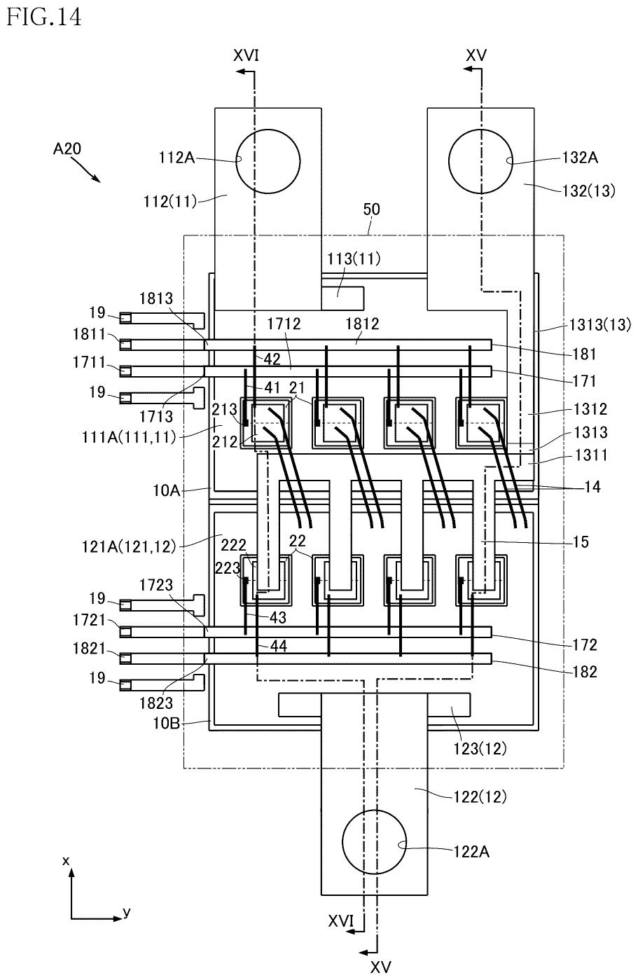

FIG. 14.

FIG. 16 is a sectional view taken along line XVI-XVI in FIG. 14.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, the expression “A surface A faces (a first side or a second side) in a direction B” is not limited to the situation where the angle of the surface A to the direction B is 90° and includes the situation where the surface A is inclined with respect to the direction B.

### First Embodiment

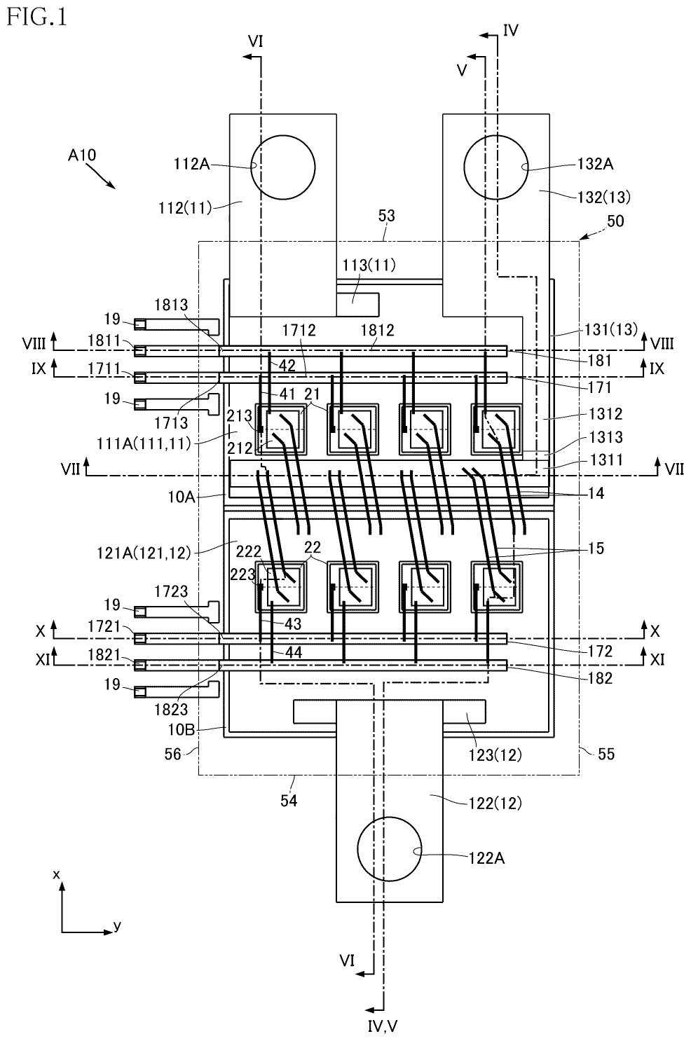

FIGS. 1 to 11 show a semiconductor device according to a first embodiment of the present disclosure. The semiconductor device A10 of the present embodiment includes a first conductive member 11, a second conductive member 12, a third conductive member 13, a plurality of fourth conductive members 14, a plurality of fifth conductive members 15, a plurality of first semiconductor elements 21, a plurality of second semiconductor elements 22, and a sealing resin 50. The semiconductor device A10 also includes a lead 171, a lead 172, a lead 181, a lead 182, a plurality of dummy terminals 19, a plurality of first wires 41, a plurality of second wires 42, a plurality of third wires 43, and a plurality of fourth wires 44. The semiconductor device A10 converts the DC power supply voltage applied to the first terminal 112 and the third terminal 132, described later, into AC power by the first second semiconductor elements 21 and the second semiconductor elements 22. The converted AC power is inputted from the second terminal 122, described later, to a power supply target, such as a motor. The semiconductor device A10 forms a part of a power conversion circuit, such as an inverter. The use and specific configuration of the semiconductor device according to the present disclosure are not limited.

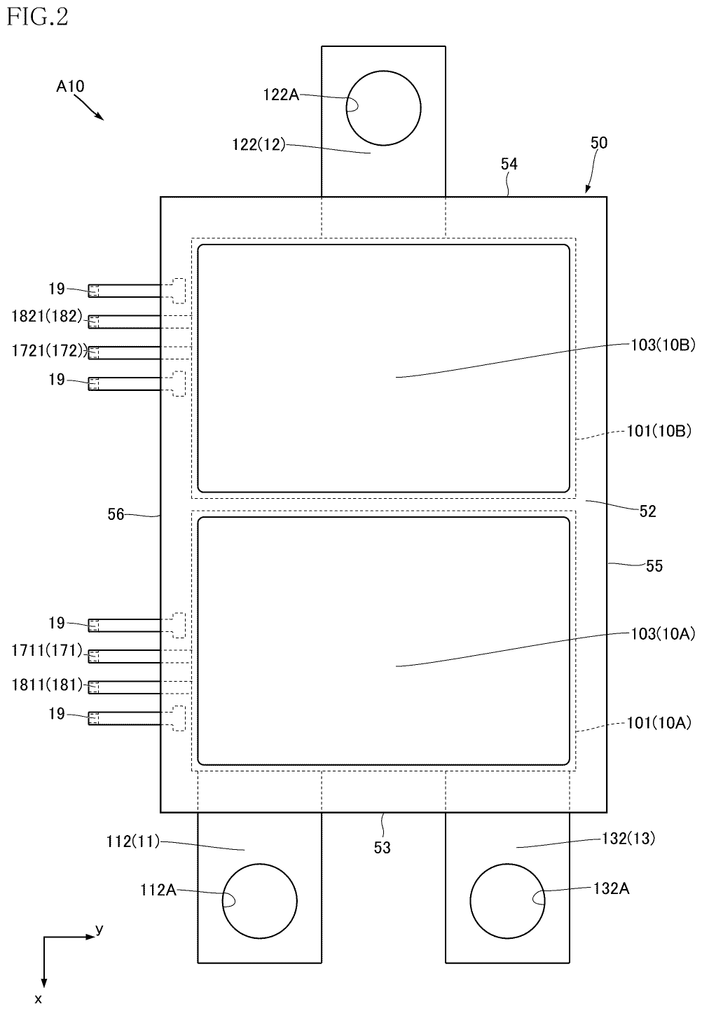

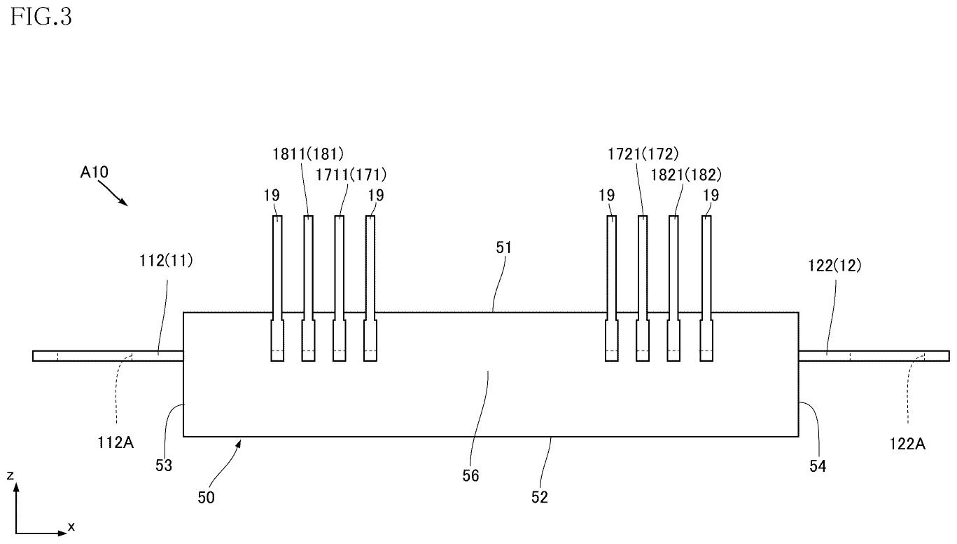

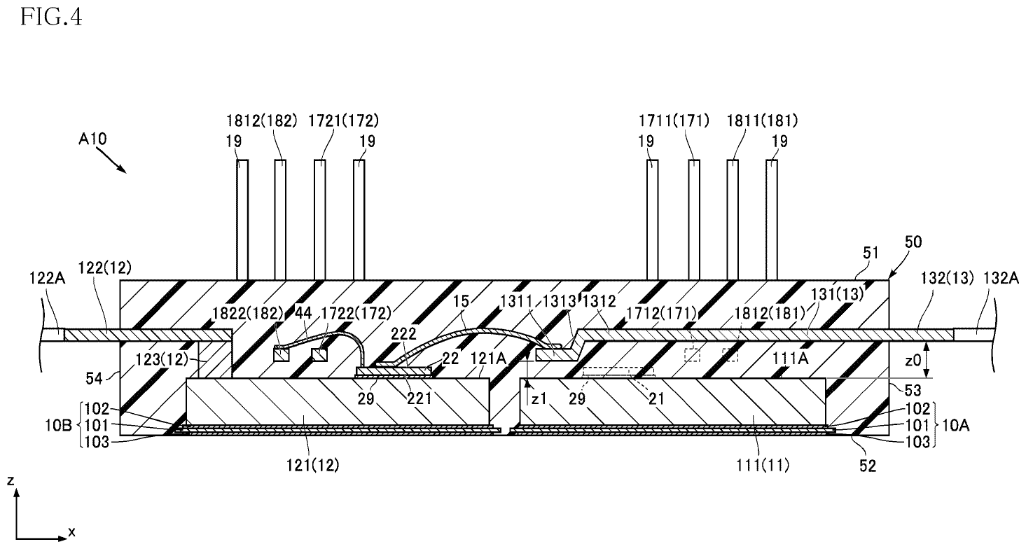

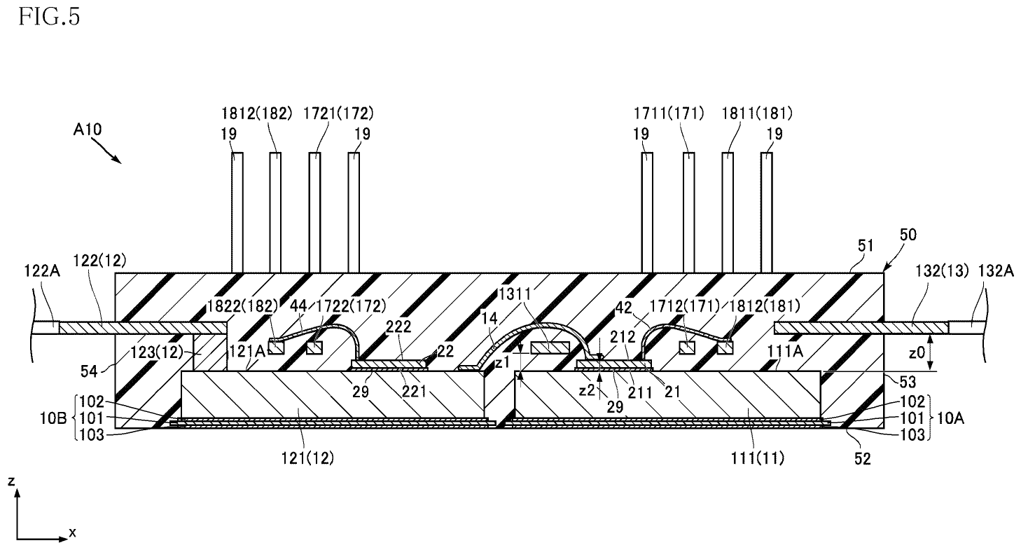

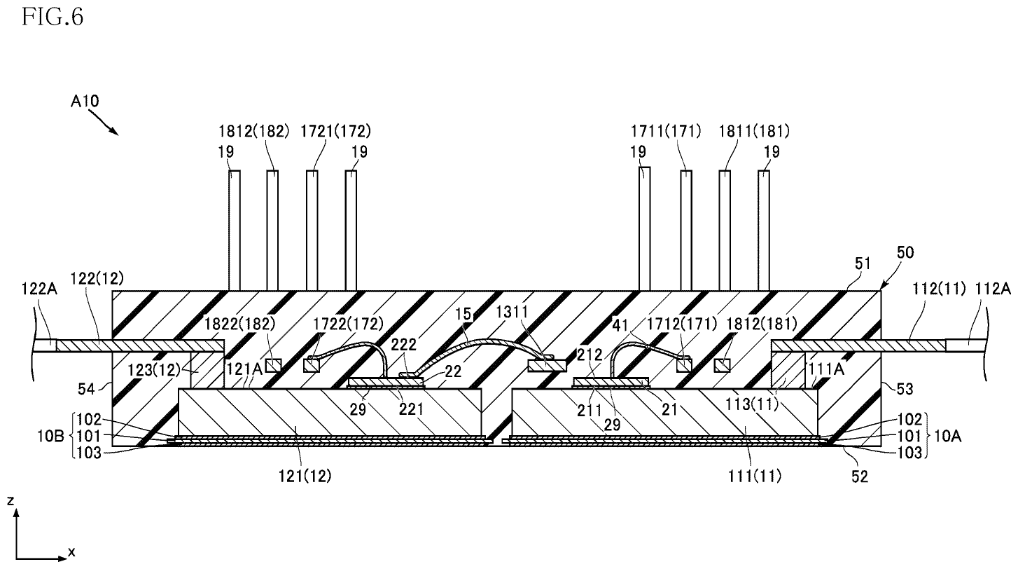

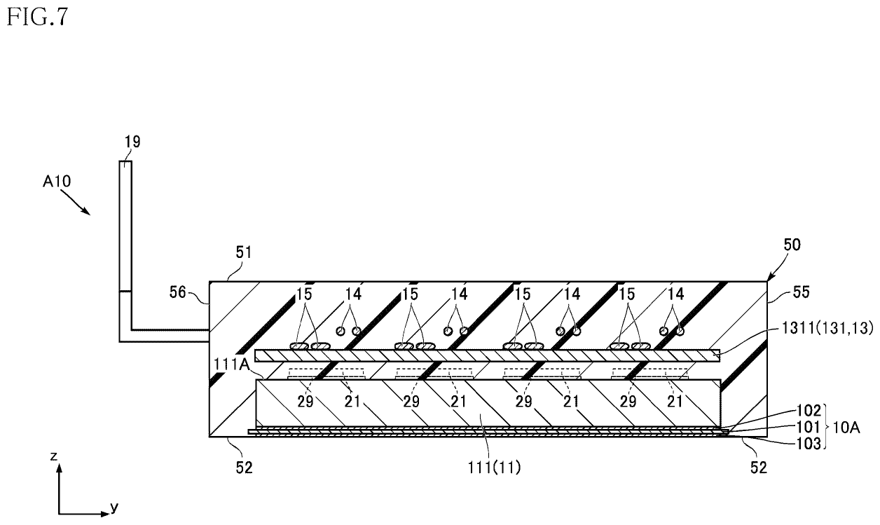

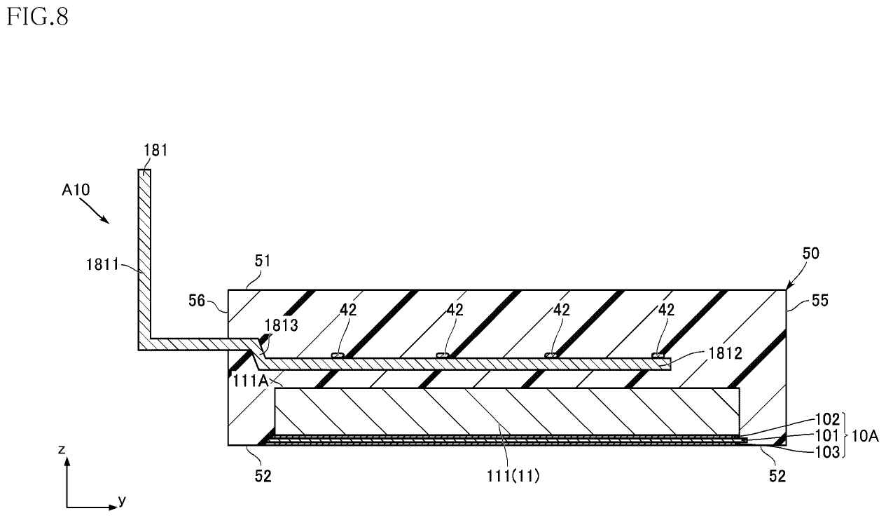

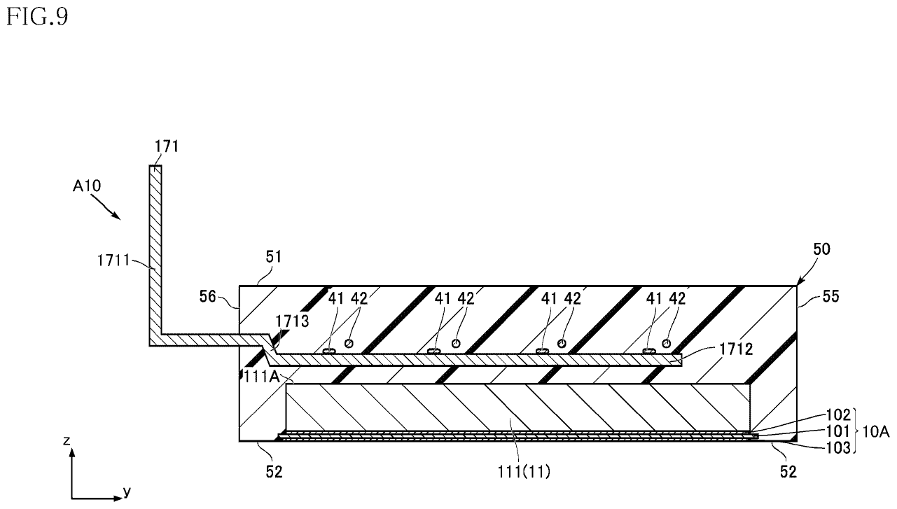

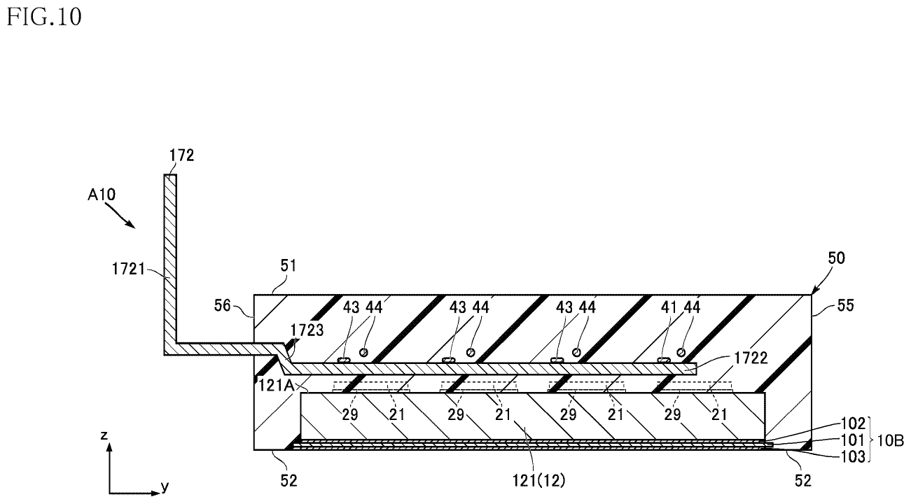

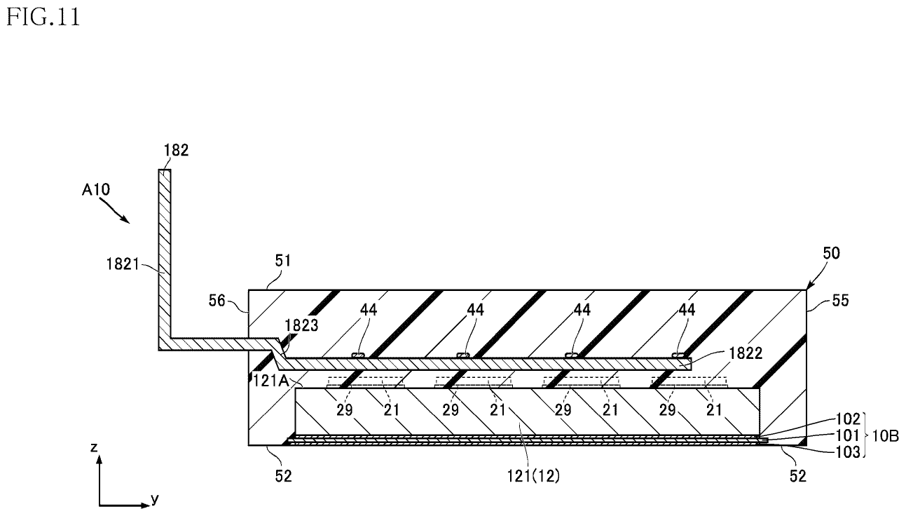

FIG. 1 is a plan view of the semiconductor device A10. FIG. 2 is a bottom view of the semiconductor device A10. FIG. 3 is a side view of the semiconductor device A10. FIG. 4 is a sectional view taken along line IV-IV in FIG. 1. FIG. 5 is a sectional view taken along line V-V in FIG. 1. FIG. 6 is a sectional view taken along line VI-VI in FIG. 1. FIG. 7 is a sectional view taken along line VII-VII in FIG. 1. FIG. 8 is a sectional view taken along line VIII-VIII in FIG. 1. FIG. 9 is a sectional view taken along line IX-IX in FIG. 1. FIG. 10 is a sectional view taken along line X-X in FIG. 1. FIG. 11 is a sectional view taken along line XI-XI in FIG. 1. In these figures, the z direction is an example of the “thickness direction”. The x direction is an example of the “first direction”, while the y direction is an example of the “second direction”. In FIG. 1, the sealing resin 50 is shown by imaginary lines.

### First Conductive Member 11:

The first conductive member 11 includes a first base 111, a first terminal 112, and a first bolster 113. The first base 111 is made of a conductive material and contains, for example, Cu (copper). The first base 111 is disposed on a first side in the x direction. The first base 111 has a first obverse surface 111A. The first obverse surface 111A faces a first side in the z direction. In the illustrated example, the first obverse surface 111A is a flat surface.

As shown in FIGS. 1, 2, and 6, the first terminal 112 protrudes toward the first side in the x direction and includes a portion exposed from the sealing resin 50. The first terminal 112 is disposed at a position offset toward the first side in the x direction with respect to the first base 111. The first terminal 112 is also offset toward a second side in the y direction with respect to the first base 111. The first terminal 112 is disposed on the first side in the z direction with respect to the first obverse surface 111A and spaced apart from the first base 111. The first terminal 112 overlaps with the first obverse surface 111A as viewed in the z direction. The composition of the first terminal 112 includes Cu (copper). The first terminal 112 has a first mounting hole 112A. The first mounting hole 112A penetrates the first terminal 112 in the z direction.

As shown in FIGS. 1 and 6, the first bolster 113 is interposed between the first base 111 and the first terminal 112. The composition of the first bolster 113 includes Cu (copper). The first bolster 113 is conductively bonded to the first obverse surface 111A of the first base 111 and the first terminal 112. The method for conductive bonding is not limited, and methods using a conductive bonding material such as solder, welding, or other methods may be used as appropriate.

In the present embodiment, the first base 111 is supported by a support member 10A as shown in FIGS. 1, 2, and 4 to 9. The support member 10A is located opposite to the first obverse surface 111A with respect to the first base 111. The specific configuration of the support member 10A is not limited. In the present embodiment, the support member 10A is provided by a DBC (Direct Bonded Copper) substrate. The support member 10A includes an insulating layer 101, a support layer 102, and a heat dissipation layer 103. The support member 10A is covered with the sealing resin 50 except a part of the heat dissipation layer 103.

The insulating layer 101 includes a portion located between the support layer 102 and the heat dissipation layer 103 in the z direction. The insulating layer 101 is made of a material with relatively high thermal conductivity. The insulating layer 101 is made of, for example, ceramic containing aluminum nitride (AlN). The thickness of the insulating layer 101 is smaller than that of the first base 111.

The support layer 102 is located between the insulating layer 101 and the first base 111 in the z direction. The composition of the support layer 102 includes copper (Cu). As viewed in the e z direction, the support layer 102 is surrounded by the periphery of the insulating layer 101. The support layer 102 is bonded to the first base 111 via, for example, solder.

The heat dissipation layer 103 is located opposite to the support layer 102 with respect to the insulating layer 101 in the z direction. A part of the heat dissipation layer 103 is exposed from the sealing resin 50. When the semiconductor device A10 is used, a heat sink (not shown), for example, is bonded to the heat dissipation layer 103. The composition of the heat dissipation layer 103 includes copper. As viewed in the z direction, the heat dissipation layer 103 is surrounded by the periphery of the insulating layer 101.

### Second Conductive Member 12:

The second conductive member 12 includes a second base 121, a second terminal 122, and a second bolster 123. The second base 121 is made of a conductive material and contains, for example, Cu (copper). The second base 121 is disposed on a second side in the x direction. The second base 121 has a second obverse surface 121A. The second obverse surface 121A faces the first side in the z direction. In the illustrated example, the second obverse surface 121A is a flat surface.

As shown in FIGS. 1 to 6, the second terminal 122 protrudes toward the second side in the x direction and includes a portion exposed from the sealing resin 50. The second terminal 122 is disposed at a position offset toward the second side in the x direction with respect to the second base 121. The center position in the y direction of the second terminal 122 generally coincides with the center position in the y direction of the second base 121. The second terminal 122 is disposed on the first side in the z direction with respect to the second obverse surface 121A and spaced apart from the second base 121. The second terminal 122 overlaps with the second obverse surface 121A as viewed in the z direction. The composition of the second terminal 122 includes Cu (copper). The second terminal 122 has a second mounting hole 122A. The second mounting hole 122A penetrates the second terminal 122 in the z direction.

As shown in FIGS. 1 and 4 to 6, the second bolster 123 is interposed between the second base 121 and the second terminal 122. The composition of the second bolster 123 includes Cu (copper). The second bolster 123 is conductively bonded to the second obverse surface 121A of the second base 121 and the second terminal 122. The method for conductive bonding is not limited, and methods using a conductive bonding material such as solder, welding, or other methods may be used as appropriate.

In the present embodiment, the second base 121 is supported by a support member 10B as shown in FIGS. 1, 2, 4 to 6, 10, and 11. The support member 10B is located opposite to the second obverse surface 121A with respect to the second base 121. The specific configuration of the support member 10B is not limited, and is the same as that of the support member 10A in the present embodiment. Thus, the description is omitted.

### First Semiconductor Element 21:

As shown in FIGS. 1 and 4 to 7, the first semiconductor elements 21 are bonded to the first obverse surface 111A of the first base 111. The first semiconductor elements 21 are identical with each other. The first semiconductor elements 21 are, for example, MOSFETS (Metal-Oxide-Semiconductor Field-Effect Transistor). Alternatively, the first semiconductor elements 21 may be field-effect transistors including MISFETS (Metal-Insulator-Semiconductor Field-Effect Transistor) or bipolar transistors such as IGBTs (Insulated Gate Bipolar Transistor). Unlike the present embodiment, the first semiconductor elements 21 may be diodes. In the semiconductor device A10 described herein, the first semiconductor elements 21 are n-channel MOSFETs of a vertical structure type. The first semiconductor elements 21 include a compound semiconductor substrate. The composition of the compound semiconductor substrate includes silicon carbide (SiC). The first semiconductor elements 21 are arranged along the y direction.

Each of the first semiconductor elements 21 has a first reverse-surface electrode a 211, first obverse-surface electrode 212, and a first gate electrode 213.

The first reverse-surface electrode 211 faces the first obverse surface 111A of the first base 111. A current corresponding to the electric power before conversion by the first semiconductor element 21 flows in the first reverse-surface electrode 211. That is, the first reverse-surface electrode 211 corresponds to the drain electrode of the first semiconductor element 21. The first reverse-surface electrode 211 is conductively bonded to the first obverse surface 111A via a conductive bonding layer 29. Thus, the first reverse-surface electrodes 211 of the plurality of first semiconductor elements 21 are electrically connected to the first conductive member 11. The conductive bonding layer 29 is, for example, solder. Alternatively, the conductive bonding layer 29 may be a sintered metal containing silver or other metals.

The first obverse-surface electrode 212 is located on the first side opposite to the first reverse-surface electrode 211 in the z direction. A current corresponding to the electric power after conversion by the first semiconductor element 21 flows in the first obverse-surface electrode 212. That is, the first obverse-surface electrode 212 corresponds to the source electrode of the first semiconductor element 21.

The first gate electrode 213 is located on the same side (the first side) as the first obverse-surface electrode 212 in the z direction. A gate voltage for driving the first semiconductor element 21 is applied to the first gate electrode 213. As shown in FIG. 3, the area of the first gate electrode 213 is smaller than the area of the first obverse-surface electrode 212 as viewed in the z direction.

### Second Semiconductor Element 22:

As shown in FIGS. 1 and 4 to 6, the second semiconductor elements 22 are bonded to the second obverse surface 121A of the second base 121. The second semiconductor elements 22 are identical with the first semiconductor elements 21. Therefore, the second semiconductor elements 22 are n-channel MOSFETs of a vertical structure type. Alternatively, the second semiconductor elements 22 may be field-effect transistors including MISFETs (Metal-Insulator-Semiconductor Field-Effect Transistor) or bipolar transistors such as IGBTs (Insulated Gate Bipolar Transistor). Unlike the present embodiment, the second semiconductor elements 22 may be diodes. In the description of the semiconductor device A10, the second semiconductor elements 22 are n-channel MOSFETs of a vertical structure type. The second semiconductor elements 22 include a compound semiconductor substrate. The composition of the compound semiconductor substrate includes silicon carbide (SiC). The second semiconductor elements 22 are arranged along the y direction.

Each of the second semiconductor elements 22 has a second reverse-surface electrode 221, a second obverse-surface electrode 222, and a second gate electrode 223.

The second reverse-surface electrode 221 faces the second obverse surface 121A of the second base 121. A current corresponding to the electric power before conversion by the second semiconductor element 22 flows in the second reverse-surface electrode 221. That is, the second reverse-surface electrode 221 corresponds to the drain electrode of the second semiconductor element 22. The second reverse-surface electrode 221 is conductively bonded to the second obverse surface 121A via a conductive bonding layer 29. Thus, the second reverse-surface electrodes 221 of the plurality of second semiconductor elements 22 are electrically connected to the second conductive member 12.

The second obverse-surface electrode 222 is located on the first side opposite to the second reverse-surface electrode 221 in the z direction. A current corresponding to the electric after power conversion by the second semiconductor element 22 flows in the second obverse-surface electrode 222. That is, the second obverse-surface electrode 222 corresponds to the source electrode of the second semiconductor element 22.

The second gate electrode 223 is located on the same side (the first side) as the second obverse-surface electrode 222 in the z direction. A gate voltage for driving the second semiconductor element 22 is applied to the second gate electrode 223. The area of the second gate electrode 223 is smaller than the area of the second obverse-surface electrode 222 as viewed in the z direction.

### Third Conductive Member:

As shown in FIGS. 1, 2, and 4 to 7, the third conductive member 13 includes an extending part 131 and a third terminal 132. The third conductive member 13 is made of a conductive material and contains, for example, Cu (copper).

The third terminal 132 includes a portion protruding from the sealing resin 50 toward the first side in the x direction. The third terminal 132 is located on a first side in the y direction with respect to the first terminal 112. The third terminal 132 is disposed at a position offset toward the first side in the x direction with respect to the first base 111. The third terminal 132 is disposed on the first side in the z direction with respect to the first obverse surface 111A and spaced apart from the first base 111. The third terminal 132 overlaps with the first obverse surface 111A as viewed in the z direction. The third terminal 132 has a third mounting hole 132A. The third mounting hole 132A penetrates the third terminal 132 in the z direction.

The extending part 131 extends from the third terminal 132 toward the second side in the x direction and is covered with the sealing resin 50. The extending part 131 of the present embodiment includes a first portion 1311, a second portion 1312, and a third portion 1313.

As shown in FIGS. 4 and 5, the distance z1 from the first obverse surface 111A to the first portion 1311 in the z direction is smaller than the distance z0 from the first obverse surface 111A to the third terminal 132 in the z direction. The distance z1 is, for example, 0.1 mm or more. As shown in FIGS. 1, 2, and 4 to 7, the first portion 1311 is located between the first semiconductor elements 21 and the second semiconductor elements 22 in the x direction. As shown in FIG. 5, in the illustrated example, the distance z1 is greater than the distance z2 in the z direction from the first obverse surface 111A to the end on the first side in the z direction of the first semiconductor element 21. For example, the distance z2 is about 0.5 mm, whereas the distance z1 is about 0.8 mm to 1.2 mm.

The shape of the first portion 1311 is not limited. In the present embodiment, the first portion 1311 extends in the y direction and has the shape of, for example, a flat strip. In the illustrated example, the first portion 1311 overlaps with the first obverse surface 111A (the first base 111) as viewed in the z direction. Also, in the illustrated example, the edge of the first portion 1311 on the second side in the x direction is located on the first side in the x direction from the edge of the first obverse surface 111A on the second side in the x direction.

The second portion 1312 is connected to the third terminal 132. The second portion 1312 extends along the x direction from the third terminal 132 toward the second side in the x direction. The second portion 1312 is not limited to a particular shape and has the shape of, for example, a flat strip. The distance from the first obverse surface 111A to the second portion 1312 in the z direction is equal to the distance z0. The second portion 1312 is located on the first side in the y direction (the right side in FIG. 1) with respect to the first semiconductor elements 21. The edge of the second portion 1312 on the second side in the x direction is located on the second side in the x direction from the edge of the first semiconductor element 21 on the first side in the x direction.

The third portion 1313 is interposed between the first portion 1311 and the second portion 1312. By including the third portion 1313, the extending part 131 has a bent shape as viewed in the y direction. In the illustrated example, the third portion 1313 is connected to a part of the first portion 1311, where the part is at the edge on the first side in the x direction and is close to the end in the y direction.

### Fourth Conductive Member 14:

As shown in FIGS. 1, 5, and 7, the plurality of fourth conductive members 14 electrically connect the first semiconductor elements 21 and the second conductive member 12 the fourth conductive individually. More specifically, are connected to members 14 the first obverse-surface electrodes 212 of the first semiconductor elements 21. The fourth conductive members 14 are not limited to a particular configuration and may be, for example, wires or ribbons containing a metallic material. Examples of the metallic material include Cu (copper), Al (aluminum), or alloys of these. The fourth conductive members 14 in the present example are wires containing Cu (copper). The number of the fourth conductive members 14 is not limited. n the illustrated example, two fourth conductive members 14 are connected to the first obverse-surface electrode 212 of each first semiconductor element 21.

The fourth conductive members 14 straddle the first portion 1311 on the first side in the z direction. That is, each fourth conductive member 14 includes a portion located away from the first portion 1311 to the first side in the z direction. In the illustrated example, the fourth conductive member 14 has a curved shape straddling the first portion 1311 on the first side in the z direction.

### Fifth Conductive Member 15:

As shown in FIGS. 1, 4, 6, and 7, the plurality of fifth conductive members 15 electrically connect the second semiconductor elements 22 and the third conductive member 13 individually. More specifically, the fifth conductive members 5 are connected to the second obverse-surface electrodes 222 of the second semiconductor elements 22. The fifth conductive members 15 are not limited to a particular configuration and may be, for example, wires, ribbons, or plates containing a metallic material. The fifth conductive members 15 may be provided by separate members from the third conductive member 13 or may be formed integrally with the third conductive member 13. In the present embodiment, the fifth conductive members 15 are configured separately from the third conductive member 13 and, for example, wires containing Cu (copper). The number of the fifth conductive members 15 is not limited. In the illustrated example, two fifth conductive members 15 are connected to the second obverse-surface electrode 222 of each second semiconductor element 22.

The fifth conductive members 15 are connected to the first portion 1311 of the extending part 131 of the third conductive member 13. As shown in FIG. 1, the fourth conductive members 14 and the fifth conductive members 15 are alternately arranged in the y direction. In the illustrated example, two fourth conductive members 14 and two fifth conductive members 15 are alternately arranged.

### Lead 171, 181:

As shown in FIGS. 1 to 6 and 9, the lead 171 includes a first gate terminal 1711, a first gate wiring portion 1712, and a stepped portion 1713. The lead 171 is a so-called lead member and includes, for example, Cu (copper) in its composition. The first gate terminal 1711 is located outside the sealing resin 50 and functions as a gate terminal for operating the first semiconductor elements 21 of the semiconductor device A10. The first gate wiring portion 1712 is located on the first side in the x direction with respect to the first semiconductor elements 21 and spaced apart from the first obverse surface 111A of the first base 111 to the first side in the z direction. The first gate wiring portion 1712 extends in the y direction. The distance from the first obverse surface 111A to the first gate wiring portion 1712 in the z direction is smaller than the distance from the first obverse surface 111A to the first gate terminal 1711 in the z direction. The first gate wiring portion 1712 and the first gate electrodes 213 of the first semiconductor elements 21 are electrically connected individually by the first wires 41. The first wires 41 are wires containing, for example, Au (gold). The stepped portion 1713 is located between the first gate terminal 1711 and the first gate wiring portion 1712. By including the stepped portion 1713, the lead 171 has a bent shape as viewed in the x direction.

As shown in FIGS. 1 to 6 and 8, the lead 181 includes a first detection terminal 1811, a first detection wiring portion 1812, and a stepped portion 1813. The lead 181 is a so-called lead member and includes, for example, Cu (copper) in its composition. The first detection terminal 1811 is located outside the sealing resin 50 and functions as a detection terminal for detecting the operating state of the first semiconductor elements 21 of the semiconductor device A10. The first detection wiring portion 1812 is located on the first side in the x direction with respect to the first gate wiring portion 1712 and spaced apart from the first obverse surface 111A of the first base 111 to the first side in the z direction. The first detection wiring portion 1812 extends in the y direction. The distance from the first obverse surface 111A to the first detection wiring portion 1812 in the z direction is smaller than the distance from the first obverse surface 111A to the first detection terminal 1811 in the z direction. The first detection wiring portion 1812 and the first obverse-surface electrodes 212 of the first semiconductor elements 21 are electrically connected individually by the second wires 42. The second wires 42 are wires containing, for example, Au (gold). The stepped portion 1813 is located between the first detection terminal 1811 and the first detection wiring portion 1812. By including the stepped portion 1813, the lead 181 has a bent shape as viewed in the x direction.

### Lead 172, 182:

As shown in FIGS. 1 to 6 and 10, the lead 172 includes a second gate terminal 1721, a second gate wiring portion 1722, and a stepped portion 1723. The lead 172 is a so-called lead member and includes, its for example, Cu (copper) in composition. The second gate terminal 1721 is located outside the sealing resin 50 and functions as a gate terminal for operating the second semiconductor elements 22 of the semiconductor device A10. The second gate wiring portion 1722 is located on the second side in the x direction with respect to the second semiconductor elements 22 and spaced apart from the second obverse surface 121A of the second base 121 to the first side in the z direction. The second gate wiring portion 1722 extends in the y direction. The distance from the second obverse surface 121A to the second gate wiring portion 1722 in the z direction is smaller than the distance from the second obverse surface 121A to the second gate terminal 1721 in the z direction. The second gate wiring portion 1722 and the second gate electrodes 223 of the second semiconductor elements 22 are electrically connected individually by the third wires 43. The third wires 43 are wires containing, for example, Au (gold). The stepped portion 1723 is located between the second gate terminal 1721 and the second gate wiring portion 1722. By including the stepped portion 1723, the lead 172 has a bent shape as viewed in the x direction.

As shown in FIGS. 1 to 6 and 11, the lead 182 includes a second detection terminal 1821, a second detection wiring portion 1822, and a stepped portion 1823. The lead 182 is a so-called lead member and includes, for example, Cu (copper) in its composition. The second detection terminal 1821 is located outside the sealing resin 50 and functions as a detection terminal for detecting the operating state of the second semiconductor elements 22 of the semiconductor device A10. The second detection wiring portion 1822 is located on the second side in the x direction with respect to the second gate wiring portion 1722 and spaced apart from the second obverse surface 121A of the second base 121 to the first side in the z direction. The second detection wiring portion 1822 extends in the y direction. The distance from the second obverse surface 121A to the second detection wiring portion 1822 in the z direction is smaller than the distance from the second obverse surface 121A to the second detection terminal 1821 in the z direction. The second detection wiring portion 1822 and the second obverse-surface electrodes 222 of the second semiconductor elements 22 are electrically connected individually by the fourth wires 44. The fourth wires 44 are wires containing, for example, Au (gold). The stepped portion 1823 is located between the second detection terminal 1821 and the second detection wiring portion 1822. By including the stepped portion 1823, the lead 182 has a bent shape as viewed in the x direction.

### Dummy Terminal 19:

As shown in FIGS. 1 to 7, the semiconductor device A10 includes four dummy terminals 19. Two of the four dummy terminals 19 are disposed to flank the first gate terminal 1711 and the first detection terminal 1811 in the x direction. The remaining two dummy terminals 19 are disposed to flank the second gate terminal 1721 and the second detection terminal 1821 in the x direction. The dummy terminals 19 are metal leads made of a material containing copper or a copper alloy. A part of each dummy terminal 19 is covered with the sealing resin. The portion of each dummy terminal 19 that stands in the z direction is exposed from the sealing resin 50.

### Sealing Resin 50:

As shown in FIGS. 1 to 11, the sealing resin 50 covers the first base 111, the second base 121, the fourth conductive members 14, the fifth conductive members 15, the first semiconductor elements 21, and the second semiconductor elements 22. The sealing resin 50 also covers a part of each of the first terminal 112, the second terminal 122 and the third terminal 132, the extending part 131, the first gate wiring portion 1712, the first detection wiring portion 1812, the second gate wiring portion 1722, and the second detection wiring portion 1822. The sealing resin 50 is electrically insulating. The sealing resin 50 is made of a material containing, for example, black epoxy resin. The sealing resin 50 has a top surface 51, a bottom surface 52, a first side surface 53, a second side surface 54, a third side surface 55, and a fourth side surface 56.

The top surface is the surface facing the first side in the z direction. The bottom surface 52 is the surface facing the second side in the z direction.

The first side surface 53 is the surface facing the first side in the x direction. The first terminal 112 and the third terminal 132 protrude from the first side surface 53. The second side surface 54 is the surface facing the second side in the x direction. The second terminal 122 protrudes from the second side surface 54.

The third side surface 55 is the surface facing the first side in the y direction. The fourth side surface 56 is the surface facing the second side in the y direction. The first gate terminal 1711, the first detection terminal 1811, the second gate terminal 1721, the second detection terminal 1821, and the dummy terminals 19 protrude from the fourth side surface 56.

Next, the effects of the semiconductor device A10 will be described.

According to the present embodiment, the first portion 1311 is located between the first semiconductor elements 21 and the second semiconductor elements 22 in the z direction as shown in FIGS. 4 to 6. The distance z1 from the first obverse surface 111A to the first portion 1311 in the z direction is smaller than the distance z0 from the first obverse surface 111A to the third terminal 132 in the z direction. Such a configuration allows reducing the distance in the z direction from the first obverse surface 111A to the fourth conductive members 14, which straddle the first portion 1311 on the first side in the z direction, while preventing contact or short-circuit between the fourth conductive members 14 and the first portion 1311. Therefore, the semiconductor device A10 allows miniaturization of the device while achieving proper operation.

As shown in FIG. 1, the first portion 1311 extends in the y direction. This allows providing a wider area for connecting the fifth conductive members 15, thereby preventing improper conduction between the fourth conductive members 14 and the fifth conductive members 15.

As shown in FIG. 5, the distance z1 from the first obverse surface 111A to the first portion 1311 in the z direction is greater than the distance z2 from the first obverse surface 111A to the end on the first side in the z direction of the first semiconductor element 21 in the z direction. This prevents, for example, the first portion 1311 from unduly interfering with the first semiconductor elements 21.

As shown in FIG. 1, the second portion 1312 is located on the first side in the y direction with respect to the first semiconductor elements 21. Therefore, it is not necessary to provide space for disposing the second portion 1312 between adjacent first semiconductor elements 21. This is favorable for miniaturization of semiconductor device A10.

The extending part 131 has a bent shape including the third portion 1313. This allows the first portion 1311 and the second portion 1312 to be located at different positions in the z direction, thereby preventing the extending part 131 from becoming large.

The fifth conductive members 15 are configured separately from the extending part 131 (the first portion 1311) of the third conductive member 13 and made of wires in the present embodiment. With such a configuration, the width (diameter) of the fifth conductive members 15 can be reduced. This configuration also allows the fifth conductive members to be connected to desired locations on the first portion 1311 and the second obverse-surface electrodes 222 of the second semiconductor elements 22, which is favorable for preventing, for example, interference or short-circuit with the fourth conductive members 14.

The first portion 1311 overlaps with the first obverse surface 111A as viewed in the z direction. This makes it easy to provide space for connecting the fourth conductive members 14 on the second obverse surface 121A.

The lead 171, the lead 181, the lead 172, and the lead 182 have the first gate wiring portion 1712, the first detection wiring portion 1812, the second gate wiring portion 1722, and the second detection wiring portion 1822, respectively. The first gate wiring portion 1712 is electrically connected to the first gate electrodes 213 of the first semiconductor elements 21 with the first wires 41.

The first detection wiring portion 1812 is electrically connected to the first obverse-surface electrodes 212 of the first semiconductor elements 21 with the second wires 42. The second gate wiring portion 1722 is electrically connected to the second gate electrode 223 of the second semiconductor elements 22 with the third wires 43. The second detection wiring portion 1822 is electrically connected to the second obverse-surface electrode 222 of the second semiconductor elements 22 with the fourth wires 44. The first gate wiring portion 1712, the first detection wiring portion 1812, the second gate wiring portion 1722 and the second detection wiring portion 1822 are portions of the lead 171, the lead 181, the lead 172, and the lead 182 and spaced apart from the first base 111 and the second base 121 in the z direction. Therefore, it is not necessary to form wiring portions that perform the functions of the first gate wiring portion 1712, the first detection wiring portion 1812, the second gate wiring portion 1722, and the second detection wiring portion 1822 on the first obverse surface 111A or the second obverse surface 121A, for example. Thus, the structure of the semiconductor device A10 is prevented from becoming complicated.

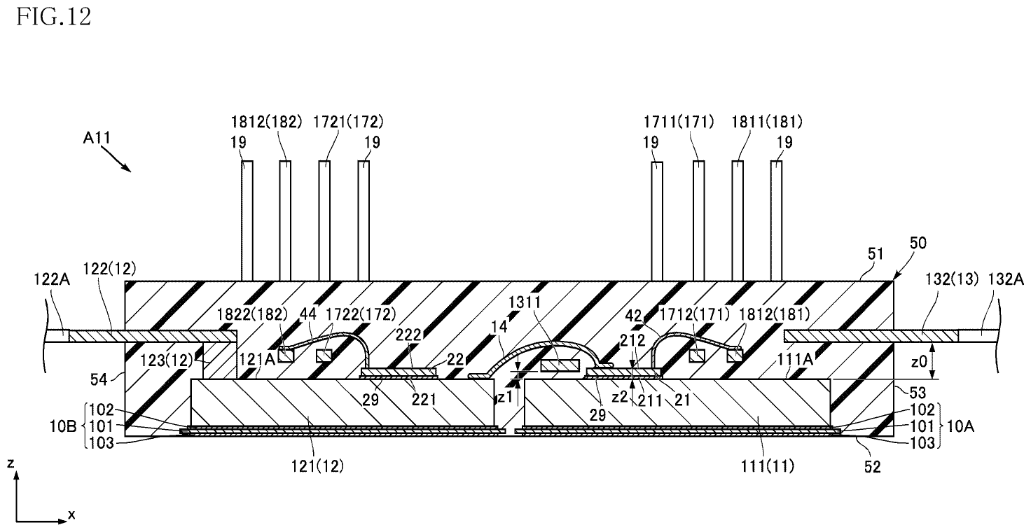

FIGS. 12 to 16 show other embodiments of the present disclosure. In these figures, the elements that are identical or similar to those of the above-described embodiment are denoted by the same reference signs as those used for the above-described embodiment. Various parts of variations and embodiments may be selectively used in any appropriate combination as long as it is technically compatible.

### First Embodiment, First Variation

FIG. 12 shows a first variation of the semiconductor device A10. The semiconductor device A11 of the present variation differs from the above example in the relationship between the first portion 1311 and the first semiconductor elements 21.

In the present variation, the distance z1 from the first obverse surface 111A to the first portion 1311 in the z direction is smaller than the distance z2 from the first obverse surface 111A to the end on the first side in the z direction of the first semiconductor element 21 in the z direction. For example, the distance z2 is about 0.5 mm, whereas the distance z1 is about 0.1 mm to 0.3 mm.

The semiconductor device A11 of the present variation also allows miniaturization of the device while achieving proper operation. Moreover, the present variation can further reduce the distance from the first obverse surface 111A to the end on the first side in the z direction of the fourth conductive members 14. This is favorable for miniaturization of the semiconductor device A11.

### First Embodiment, Second Variation

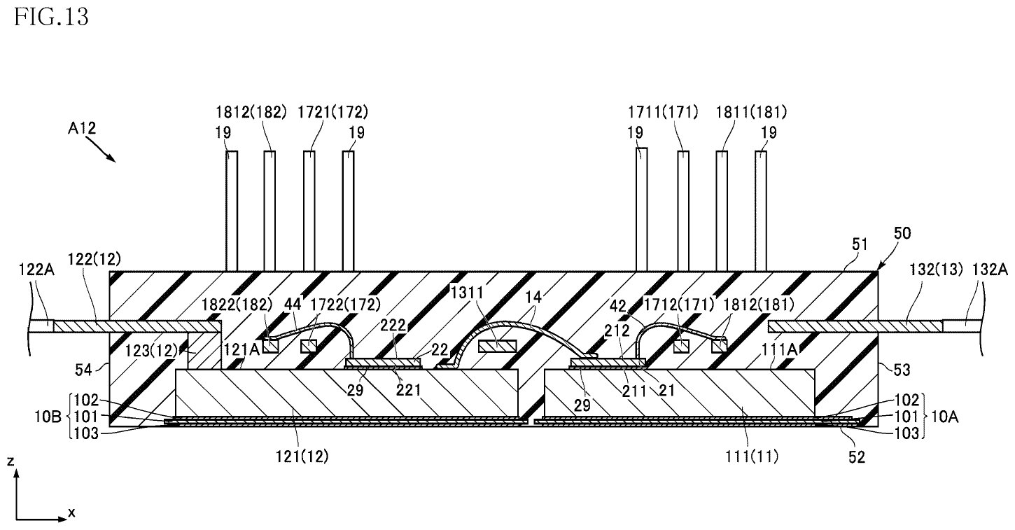

FIG. 13 shows a second variation of the semiconductor device A10. The semiconductor device A12 of the present variation differs from the above examples in the relationship between the first portion 1311 and the first and the second bases 111 and 121.

In the present variation, the first portion 1311 overlaps with the second obverse surface 121A (the second base 121) as viewed in the z direction. In the illustrated example, the edge of the first portion 1311 on the first side in the x direction overlaps with the edge of the second obverse surface 121A on the first side in the x direction or is located on the second side in the x direction from the edge of the second obverse surface 121A on the first side in the x direction.

The semiconductor device A12 of the present variation also allows miniaturization of the device while achieving proper operation. As understood from the present variation, the first portion 1311 may be configured to overlap with the first obverse surface 111A or may be configured to overlap with the second obverse surface 121A as viewed in the z direction.

### Second Embodiment

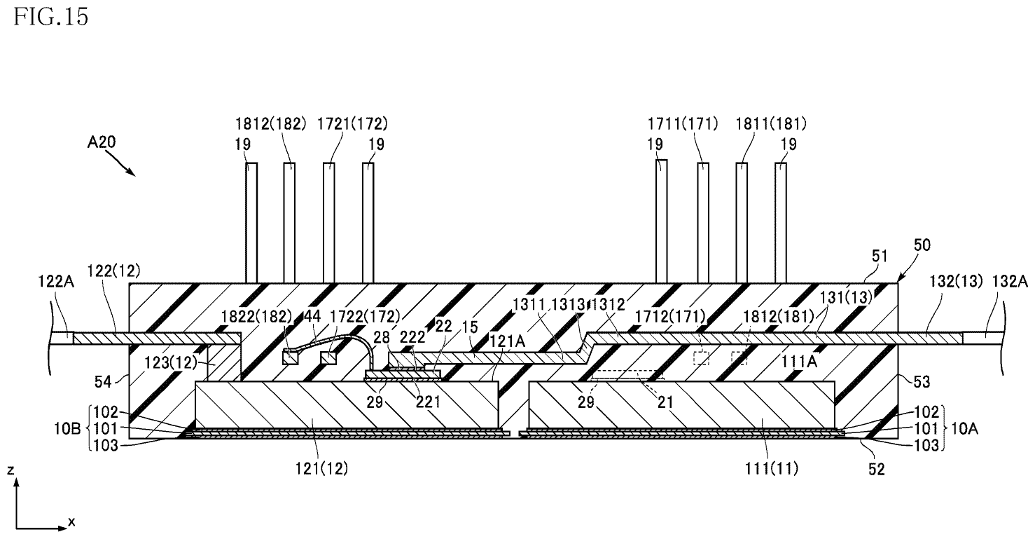

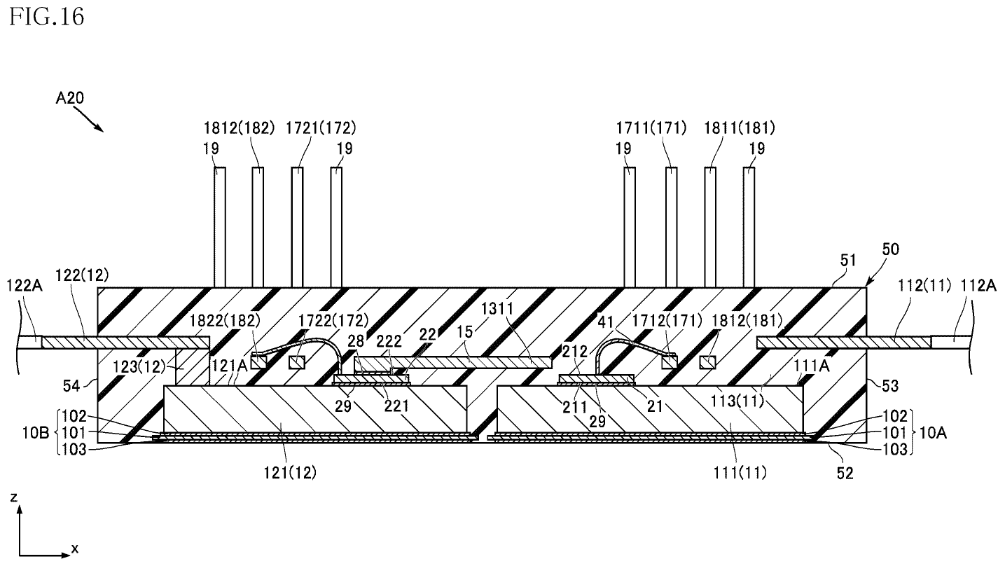

FIGS. 14 to 16 show a semiconductor device according to a second embodiment the present disclosure. The semiconductor device A20 of the present embodiment differs from the above-described embodiment in the configurations of the third conductive member 13 and the fifth conductive members 15. FIG. 14 is a plan view showing the semiconductor device A20. FIG. 15 is a sectional view taken along line XV-XV in FIG. 14. FIG. 16 is a sectional view taken along line XVI-XVI in FIG. 14.

In the present embodiment, the fifth conductive members 15 are formed integrally with the third conductive member 13. More specifically, the fifth conductive members 15 extend from the third conductive member 13 toward the second side in the x direction. The fifth conductive members 15 are arranged side by side in the y direction. The distance from the first obverse surface 111A and the second obverse surface 121A to the fifth conductive members 15 in the z direction is equal to the distance from the first obverse surface 111A to the first portion 1311 in the z direction.

The fifth conductive members 15 are bonded to the second obverse-surface electrodes 222 of the second semiconductor elements 22 with, for example, conductive bonding layers 28. The conductive bonding layers 28 are, for example, solder. Alternatively, the conductive bonding layers 28 may be a sintered metal containing silver or other metals.

The semiconductor device A20 of the present embodiment also allows miniaturization of the device while achieving proper operation. As understood from the present embodiment, the fifth conductive members 15 may be formed integrally with the first portion 1311 of the third conductive member 13. Forming the fifth conductive members 15 integral with the third conductive member 13 by a so-called lead member can further reduce the resistance.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

### Clause 1.

A semiconductor device comprising:
a first conductive member including a first obverse surface facing a first side in a thickness direction and disposed on a first side in a first direction orthogonal to the thickness direction;
a second conductive member including a second obverse surface facing the first side in the thickness direction and disposed on a second side in the first direction;
a first semiconductor element conductively bonded to the first obverse surface;
a second semiconductor element conductively bonded to the second obverse surface;
a third conductive member;
a fourth conductive member electrically connecting the first semiconductor element and the second conductive member;
a fifth conductive member electrically connecting the second semiconductor element and the third conductive member; and
a sealing resin covering a part of each of the first conductive member, the second conductive member and the third conductive member and covering the first semiconductor element, the second semiconductor element, the fourth conductive member and the fifth conductive member, wherein
the third conductive member includes a third terminal protruding from the sealing resin toward the first side in the first direction and an extending part covered with the sealing resin,
the extending part includes a first portion located between the first semiconductor element and the second semiconductor element in the first direction, a distance from the first obverse surface to the first portion in the thickness direction being smaller than a distance from the first obverse surface to the third terminal in the thickness direction,
the fifth conductive member is connected to the second semiconductor element and the first portion; and
the fourth conductive member straddles the first portion on the first side in the thickness direction.

### Clause 2.

The semiconductor device according to clause 1, wherein the first portion extends in a second direction orthogonal to the thickness direction and the first direction.

### Clause 3.

The semiconductor device according to clause 2, comprising: a plurality of said first semiconductor elements arranged in the second direction; and
a plurality of said fourth conductive members connected to the plurality of first semiconductor elements, respectively.

### Clause 4.

The semiconductor device according to clause 3, comprising: a plurality of said second semiconductor elements arranged in the second direction; and
a plurality of said fifth conductive members connected to the plurality of second semiconductor elements, respectively.

### Clause 5.

The semiconductor device according to clause 4, wherein the distance from the first obverse surface to the first portion in the thickness direction is greater than a distance from the first obverse surface to a top portion of the first semiconductor element in the thickness direction.

### Clause 6.

The semiconductor device according to clause 4, wherein the distance from the first obverse surface to the first portion in the thickness direction is smaller than a distance from the first obverse surface to a top portion of the first semiconductor element in the thickness direction.

### Clause 7.

The semiconductor device according to any one of clauses 4 to 6, wherein the extending part includes a second portion connected to the third terminal, a distance from the first obverse surface to the second portion in the thickness direction being equal to the distance from the first obverse surface to the third terminal in the thickness direction.

### Clause 8.

The semiconductor device according to clause 7, wherein the second portion is located on a first side in the second direction with respect to the plurality of first semiconductor elements.

### Clause 9.

The semiconductor device according to clause 8, wherein the second portion extends in the first direction.

### Clause 10.

The semiconductor device according to clause 9, wherein the extending part includes a third portion interposed between the first portion and the second portion.

### Clause 11.

The semiconductor device according to any one of clauses 4 to 10, wherein the fifth conductive member is configured separately from the third conductive member.

### Clause 12.

The semiconductor device according to any one of clauses 4 to 10, wherein the fifth conductive member is formed integrally with the third conductive member.

### Clause 13.

The semiconductor device according to any one of clauses 4 to 12, wherein the first conductive member includes a first terminal protruding from the sealing resin toward the first side in the first direction and located on a second side in the second direction with respect to the third terminal.

### Clause 14.

The semiconductor device according to clause 13, wherein the second conductive member includes a second terminal protruding from the sealing resin toward the second side in the first direction.

### Clause 15.

The semiconductor device according to any one of clauses 4 to 14, wherein the first portion overlaps with the first obverse surface as viewed in the thickness direction.

### Clause 16.

The semiconductor device according to any one of clauses 4 to 14, wherein the first portion overlaps with the second obverse surface as viewed in the thickness direction.

### Clause 17.

The semiconductor device according to any one of clauses 1 to 16, wherein the first semiconductor element and the second semiconductor element are switching elements.

REFERENCE NUMERALS

| | |
|---|---|
| A10, A11, A12, A20: Semiconductor device | |
| 10A, 10B: Support member | 11: First conductive member |
| 12: Second conductive member | 13: Third conductive member |
| 14: Fourth conductive member | 15: Fifth conductive member |
| 19: Dummy terminal | 21: First semiconductor element |
| 22: Second semiconductor element | |
| 28: Conductive bonding layer | |
| 29: Conductive bonding layer | 41: First wire |
| 42: Second wire | 43: Third wire |
| 44: Fourth wire | 50: Sealing resin |
| 51: Top surface | 52: Bottom surface |
| 53: First side surface | 54: Second side surface |
| 55: Third side surface | 56: Fourth side surface |
| 101: Insulating layer | 102: Support layer |
| 103: Heat dissipation layer | 111: First base |
| 111A: First obverse surface | 112: First terminal |
| 112A: First mounting hole | 113: First bolster |
| 121: Second base | 121A: Second obverse surface |
| 122: Second terminal | 122A: Second mounting hole |
| 123: Second bolster | 131: Extending part |
| 132: Third terminal | 132A: Third mounting hole |
| 171, 172, 181, 182: Lead | |
| 211: First reverse-surface electrode | |
| 212: First obverse-surface electrode | |
| 213: First gate electrode | |
| 221: Second reverse-surface electrode | |
| 222: Second obverse-surface electrode | |
| 223: Second gate electrode | |
| 1311: First portion | 1312: Second portion |
| 1313: Third portion | 1711: First gate terminal |
| 1712: First gate wiring portion | 1713: Stepped portion |
| 1721: Second gate terminal | 1722: Second gate wiring portion |
| 1723: Stepped portion | 1811: First detection terminal |
| 1812: First detection wiring portion | 1813: Stepped portion |
| 1821: Second detection terminal | |
| 1822: Second detection wiring portion | |
| 1823: Stepped portion | z0, z1, z2: Distance |

1. A semiconductor device comprising:
a first conductive member including a first obverse surface facing a first side in a thickness direction and disposed on a first side in a first direction orthogonal to the thickness direction;
a second conductive member including a second obverse surface facing the first side in the thickness direction and disposed on a second side in the first direction;
a first semiconductor element conductively bonded to the first obverse surface;
a second semiconductor element conductively bonded to the second obverse surface;
a third conductive member;
a fourth conductive member electrically connecting the first semiconductor element and the second conductive member;
a fifth conductive member electrically connecting the second semiconductor element and the third conductive member; and
a sealing resin covering a part of each of the first conductive member, the second conductive member and the third conductive member and covering the first semiconductor element, the second semiconductor element, the fourth conductive member and the fifth conductive member, wherein
the third conductive member includes a third terminal protruding from the sealing resin toward the first side in the first direction and an extending part covered with the sealing resin,
the extending part includes a first portion located between the first semiconductor element and the second semiconductor element in the first direction, a distance from the first obverse surface to the first portion in the thickness direction being smaller than a distance from the first obverse surface to the third terminal in the thickness direction,
the fifth conductive member is connected to the second semiconductor element and the first portion; and
the fourth conductive member straddles the first portion on the first side in the thickness direction.

2. The semiconductor device according to claim 1, wherein the first portion extends in a second direction orthogonal to the thickness direction and the first direction.

3. The semiconductor device according to claim 2, comprising:
a plurality of said first semiconductor elements arranged in the second direction; and
a plurality of said fourth conductive members connected to the plurality of first semiconductor elements, respectively.

4. The semiconductor device according to claim 3, comprising:
a plurality of said second semiconductor elements arranged in the second direction; and
a plurality of said fifth conductive members connected to the plurality of second semiconductor elements, respectively.

5. The semiconductor device according to claim 4, wherein the distance from the first obverse surface to the first portion in the thickness direction is greater than a distance from the first obverse surface to a top portion of the first semiconductor element in the thickness direction.

6. The semiconductor device according to claim 4, wherein the distance from the first obverse surface to the first portion in the thickness direction is smaller than a distance from the first obverse surface to a top portion of the first semiconductor element in the thickness direction.

7. The semiconductor device according to claim 4, wherein the extending part includes a second portion connected to the third terminal, a distance from the first obverse surface to the second portion in the thickness direction being equal to the distance from the first obverse surface to the third terminal in the thickness direction.

8. The semiconductor device according to claim 7, wherein the second portion is located on a first side in the second direction with respect to the plurality of first semiconductor elements.

9. The semiconductor device according to claim 8, wherein the second portion extends in the first direction.

10. The semiconductor device according to claim 9, wherein the extending part includes a third portion interposed between the first portion and the second portion.

11. The semiconductor device according to claim 4, wherein the fifth conductive member is configured separately from the third conductive member.

12. The semiconductor device according to claim 4, wherein the fifth conductive member is formed integrally with the third conductive member.

13. The semiconductor device according to claim 4, wherein the first conductive member includes first terminal protruding from the sealing resin toward the first side in the first direction and located on a second side in the second direction with respect to the third terminal.

14. The semiconductor device according to claim 13, wherein the second conductive member includes a second terminal protruding from the sealing resin toward the second side in the first direction.

15. The semiconductor device according to claim 4, wherein the first portion overlaps with the first obverse surface as viewed in the thickness direction.

16. The semiconductor device according to claim 4, wherein the first portion overlaps with the second obverse surface as viewed in the thickness direction.

17. The semiconductor device according to claim 1, wherein the first semiconductor element and the second semiconductor element are switching elements.
